(19) United States
(12) Patent Application Publication
(10) Pub. No.: US 2024/0371883 A1
(43) Pub. Date: Nov. 7, 2024

(54) METHODS FOR MAKING SEMICONDUCTOR DEVICES INCLUDING LOCALIZED SEMICONDUCTOR-ON-INSULATOR (SOI) REGIONS

(71) Applicant: ATOMERA INCORPORATED, LOS GATOS, CA (US)

(72) Inventors: DONGHUN KANG, SAN JOSE, CA (US); HIDEKI TAKEUCHI, SAN JOSE, CA (US); KEITH DORAN WEEKS, CHANDLER, AZ (US); YI-ANN CHEN, CAMPBELL, CA (US)

(21) Appl. No.: 18/654,178

(22) Filed: May 3, 2024

Related U.S. Application Data
(60) Provisional application No. 63/499,772, filed on May 3, 2023.

(51) Int. Cl. H01L 27/12; H01L 21/02; H01L 21/762; H01L 21/8238; H01L 29/10

(52) U.S. Cl. CPC H01L 27/1207; H01L 21/02507; H01L 21/7624; H01L 21/823807; H01L 29/1054

(57) ABSTRACT

A method for making a semiconductor device may include forming buried spaced-apart insulator regions in a semiconductor substrate, and forming a monocrystalline semiconductor layer on the semiconductor substrate defining respective localized semiconductor on insulator (SOI) regions above the buried insulator regions, and respective localized bulk semiconductor regions laterally between adjacent SOI regions. The method may also include forming a superlattice in the monocrystalline semiconductor layer. The superlattice may include stacked groups of layers, with each group of layers including stacked base semiconductor monolayers defining a base semiconductor portion, and at least one non-semiconductor monolayer constrained within a crystal lattice of adjacent base semiconductor portions. The method may further include forming semiconductor devices in the monocrystalline layer, with some of the semiconductor devices in the localized SOI regions, and some other semiconductor devices in the localized bulk semiconductor regions.

### CROSS-REFERENCE TO RELATED APPLICATIONS

This application claims the benefit of U.S. provisional app. No. 63/499,772 filed May 3, 2023, which is hereby incorporated herein in its entirety by reference.

### TECHNICAL FIELD

The present disclosure generally relates to semiconductor devices, and, more particularly, to methods for making semiconductor devices with localized semiconductor-on-insulator (SOI) regions.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include forming buried spaced-apart insulator regions in a semiconductor substrate, and forming a monocrystalline semiconductor layer on the semiconductor substrate defining respective localized semiconductor on insulator (SOI) regions above the buried insulator regions, and respective localized bulk semiconductor regions laterally between adjacent SOI regions. The method may also include forming a superlattice in the monocrystalline semiconductor layer. The superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. The method may further include forming semiconductor devices in the monocrystalline layer, with some of the semiconductor devices in the localized SOI regions, and some other semiconductor devices in the localized bulk semiconductor regions.

In some embodiments, the method may further include forming a plurality of spaced-apart isolated oxide (e.g., shallow trench isolation (STI)) regions in the monocrystalline semiconductor layer. Moreover, at least some of the isolated oxide regions may extend downwardly to an adjacent buried insulator region. The method may further include positioning at least one memory circuit die above the monocrystalline semiconductor layer and coupled with the plurality of semiconductor devices.

In an example implementation, the method may include forming a plurality of optical waveguides in the monocrystalline semiconductor layer. By way of example, the optical waveguides may comprise an oxide. Moreover, forming the plurality of semiconductor devices may comprise forming at least one of an optical detector and an optical source. Also in some example configurations, forming the plurality of waveguides may comprise forming a plurality of levels of waveguides.

By way of example, the base semiconductor monolayers comprise silicon, and the non-semiconductor monolayers may comprise oxygen. Also by way of example, the buried insulator regions may comprise an oxide.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4-9 are a series of cross-sectional diagrams illustrating a method of making a semiconductor devices with localized SOI and bulk semiconductor regions on the same wafer.

FIG. 10 is a cross-sectional diagram illustrating an optical semiconductor device including waveguide devices fabricated using the localized SOI and bulk region approach shown in FIGS. 4-9.

FIG. 11 is a cross-sectional diagram of the optical semiconductor device of FIG. 10 taken along line A-A.

FIG. 12 is a cross-sectional diagram of a memory device including the semiconductor device of FIG. 9 in an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

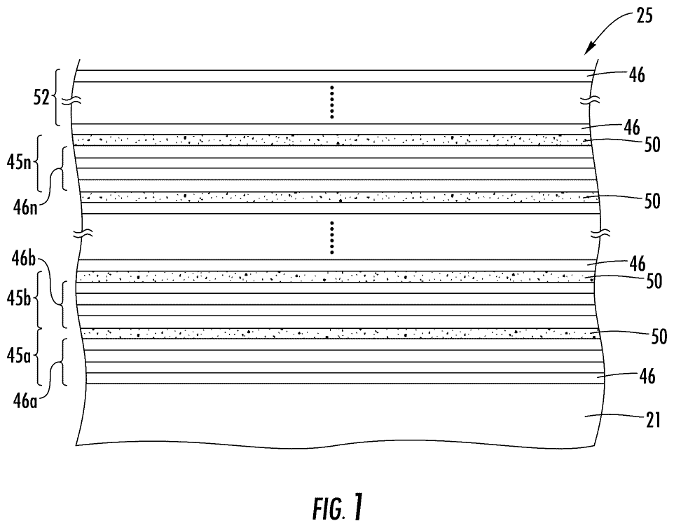

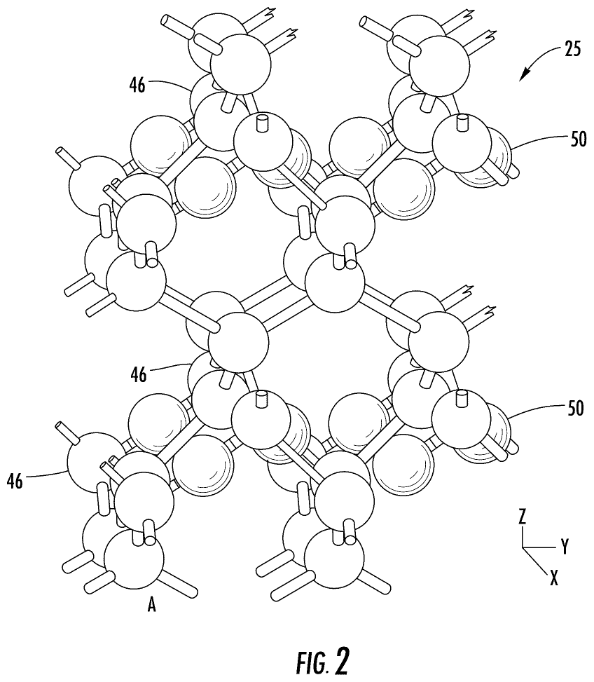

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

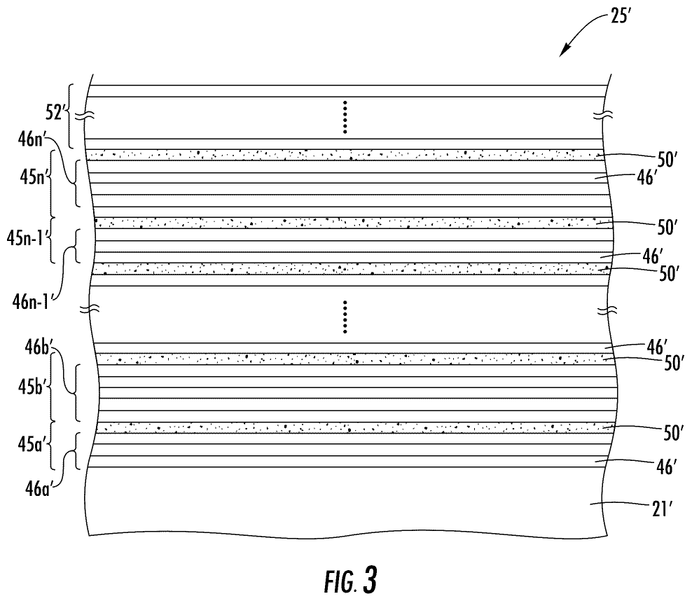

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

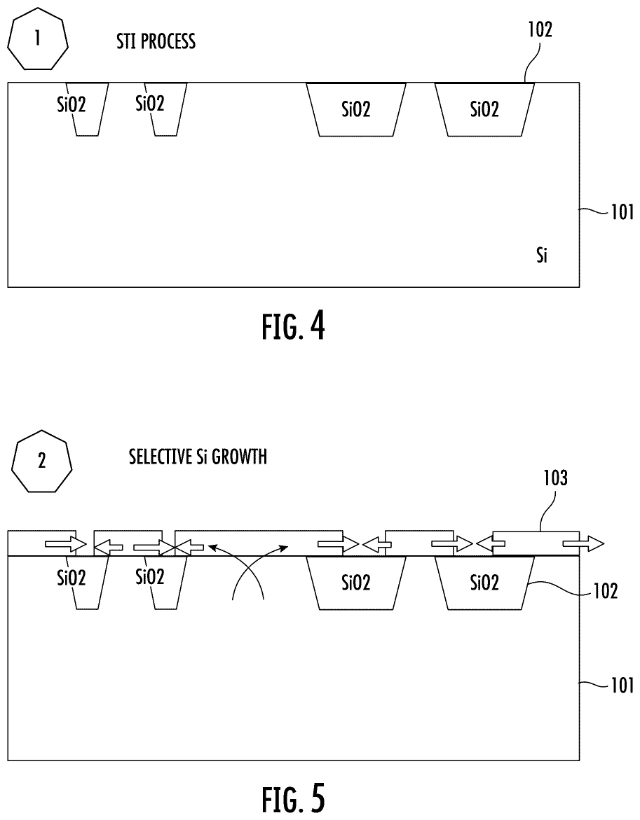

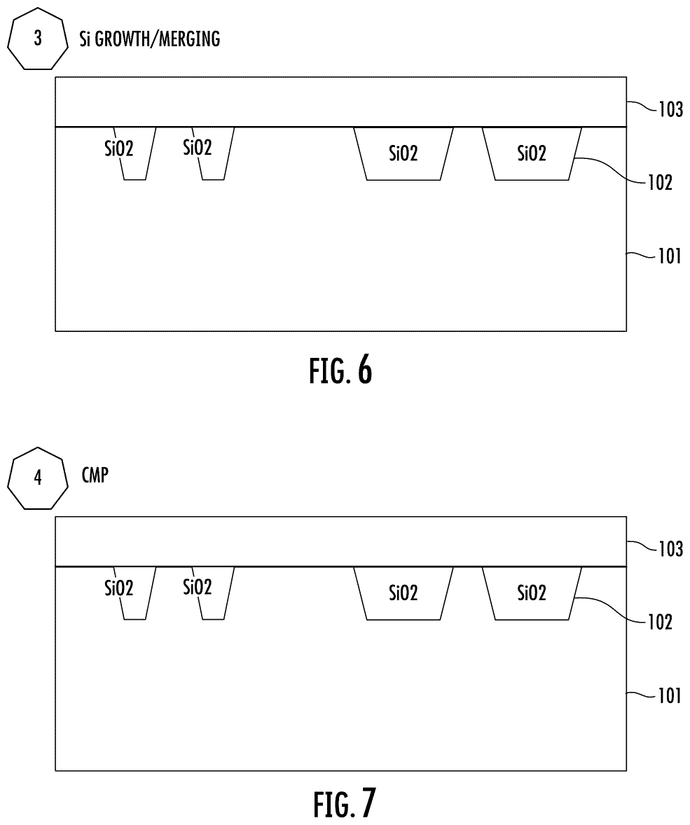

Turning to FIGS. 4-9, a method for making a semiconductor device 100 including localized semiconductor-on-insulator (SOI) regions is first described. The method begins (FIG. 4) with the formation of localized isolation regions 102 (e.g., SiO₂) spaced apart in a semiconductor (e.g., Si) wafer or substrate 101. Then an epitaxial layer 103 growth is performed (FIG. 5), in which epitaxial silicon is selectively grown laterally over each of the isolation regions from either side thereof until it laterally merges (FIG. 6) and the desired thickness is achieved. It should be noted that other insulators and semiconductor materials may be used in different embodiments. Thereafter, chemical-mechanical polishing (CMP) or other smoothing operations may be performed (FIG. 7).

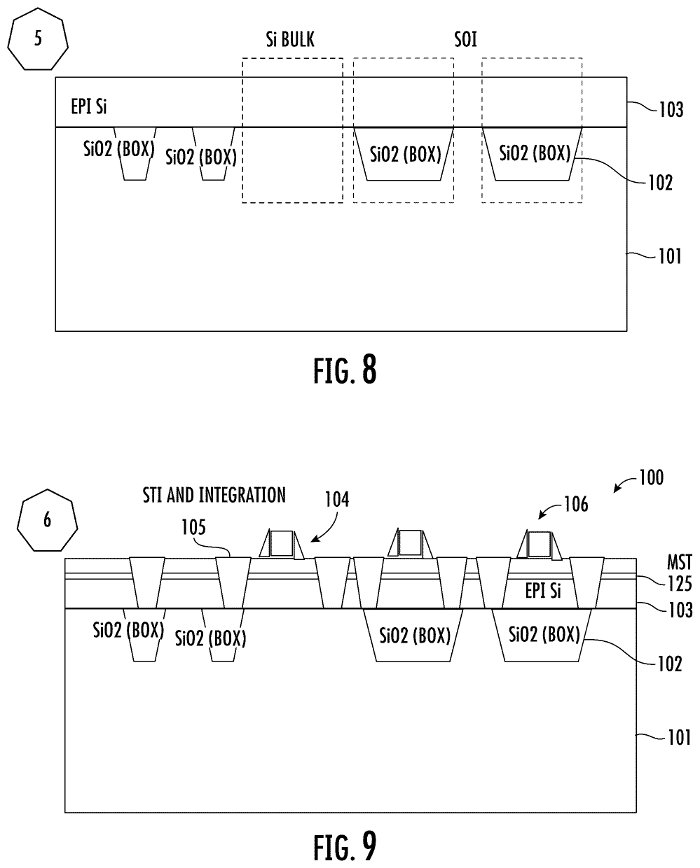

In this way, the wafer 101 effectively becomes a hybrid wafer with localized bulk semiconductor regions, as well as localized buried oxide (BOX) regions where the isolation regions 102 are present (FIG. 8). Considered alternatively, this approach allows for the growth of an SOI-like structure on a bulk silicon wafer, effectively providing a hybrid substrate on which different types of structures may be fabricated (FIG. 9). Here, a first planar MOSFET 104 is formed on the epitaxial layer 103 between adjacent isolated oxide (e.g., shallow trench isolation (STI)) regions 105 over a bulk silicon region of the substrate, while second planar MOSFETs 106 are formed on the epitaxial layer between adjacent STI regions and over localized BOX regions 102 in the substrate. However, it will be appreciated that other types of devices may be used instead of (or in addition to) MOSFETs in different embodiments (e.g., FINFETs, trench FETs, gate-all-around (GAA) devices, CFET, 2D FET etc.). In one example implementation, a combination of RF and non-RF devices 106 may be included in the device 100, with the RF devices located in the localized BOX regions. One or more MST films 125 may also be incorporated in the epitaxial layer 103 to provide enhanced conductivity and/or dopant retention features as applicable, as discussed further above. It should be noted that the MST film(s) 125 may be located elsewhere depending on the given application or implementation.

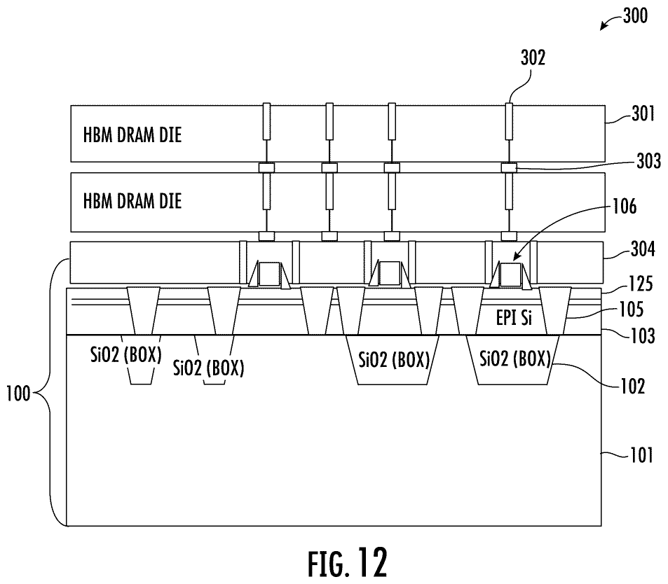

Referring additionally to FIG. 12, in one example implementation, the semiconductor device 100 may be utilized as a logic die for stacked DRAM die 301 in a high bandwidth memory (HBM) device 300. Connections for the semiconductor devices 106 are within a dielectric layer 304 and are electrically coupled with the DRAM die 301 circuitry by through silicon vias (TSVs) and conductive bumps 303 as shown. While two DRAM die 301 are shown in FIG. 12, it will be appreciated that a single die, or more than two die, may be used in different embodiments.

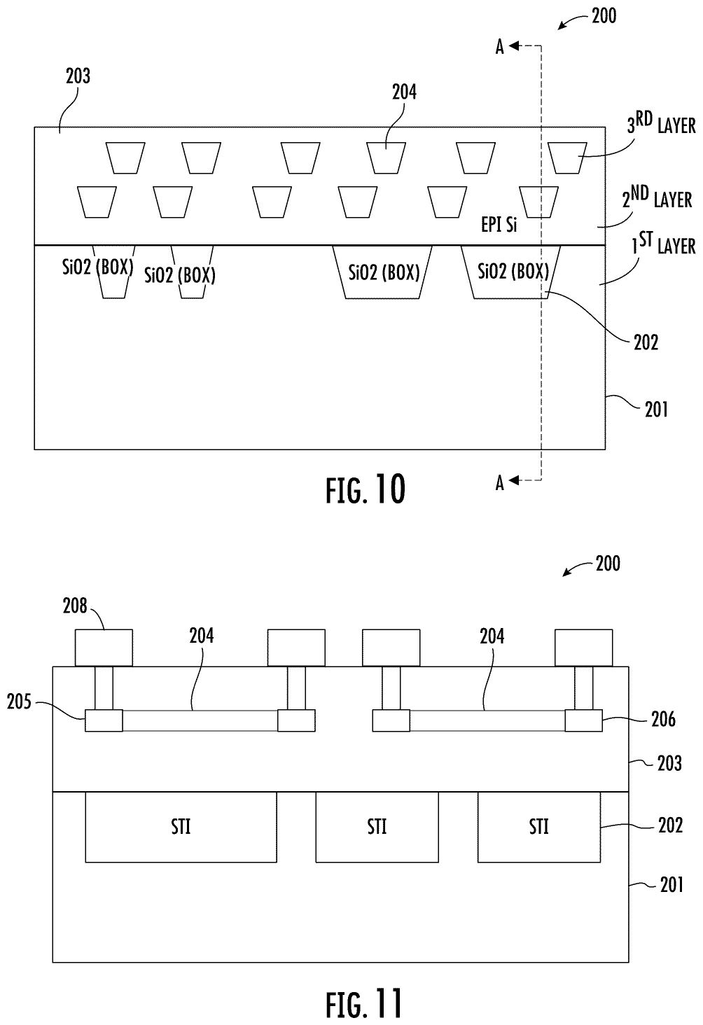

Referring additionally to FIGS. 10-11, the above-described approach to forming localized SOI and bulk regions may be used to fabricate an optical semiconductor device 200. More particularly, BOX regions 202 are formed in a substrate or wafer 201, follow by lateral epitaxial growth over the box regions to form the semiconductor layer 203. Additional regions 204 (e.g., SiO₂) may be formed in the semiconductor layer 203 to define waveguides throughout the device 200 in multiple stacked layers to define a three-dimensional (3D) configuration. That is, the above-described lateral overgrowth approach may be repeated to generate multiple layers or levels of regions 204 (or other structures such as interconnect layers, etc.). In the illustrated example, there are two levels of waveguides in the epitaxial (monocrystalline) layer 203, and waveguides in the second level are laterally offset from waveguides in the third level. MST layers may be incorporated adjacent the waveguides for optical transmission, for example.

The optical semiconductor device 200 further illustratively includes a respective optical source (modulator) 205 and an optical detector 206 for each waveguide. Respective conductive (e.g., metal) vias 207 may contact the optical sources 205 and detectors 206, which are in turn connected to respective contacts 208 on the surface of the epitaxial layer 203. Other optical source/detector configurations are also possible in different embodiments, as will be appreciated by those skilled in the art.

It should be noted that the technique illustrated in FIG. 10 of repeated lateral overgrowth to define multiple device layers may be used for other devices, such as those shown in FIG. 9, if desired. Moreover, this approach may be used to combine both optical and electronic devices on the same wafer as well. In particular, the above-described approach may be used for numerous applications such as CMOS, mixed signal and optical (waveguide) devices, etc.

The above-described approach provides numerous technological advantages. More particularly, it allows for location generation of an SOI structure within a bulk wafer (e.g., Si wafer). As a result, this may be more cost effective than typical SOI processes. Moreover, it allows for both bulk and SOI (BOX) devices to be integrated into the same wafer. Furthermore, this approach is MST film growth compatible, allowing for the growth of one or more MST films in various locations for enhanced conductivity and/or dopant blocking/retention applications.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A method for making a semiconductor device comprising:
forming a plurality of buried spaced-apart insulator regions in a semiconductor substrate;
forming a monocrystalline semiconductor layer on the semiconductor substrate defining respective localized semiconductor on insulator (SOI) regions above the buried insulator regions, and respective localized bulk semiconductor regions laterally between adjacent SOI regions;
forming a superlattice in the monocrystalline semiconductor layer, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
forming a plurality of semiconductor devices in the monocrystalline layer, with at least some of the semiconductor devices in the localized SOI regions, and at least some other semiconductor devices in the localized bulk semiconductor regions.

2. The method of claim 1 further comprising forming a plurality of spaced-apart isolated oxide regions in the monocrystalline semiconductor layer.

3. The method of claim 2 wherein at least some of the isolated oxide regions extend downwardly to an adjacent buried insulator region.

4. The method of claim 1 comprising forming a plurality of optical waveguides in the monocrystalline semiconductor layer.

5. The method of claim 4 wherein the optical waveguides comprise an oxide.

6. The method of claim 4 wherein forming the plurality of semiconductor devices comprises forming at least one of an optical detector and an optical source.

7. The method of claim 4 wherein forming the plurality of waveguides comprises forming a plurality of levels of waveguides.

8. The method of claim 1 further comprising positioning at least one memory circuit die above the monocrystalline semiconductor layer and coupled with the plurality of semiconductor devices.

9. The method of claim 1 wherein the base semiconductor monolayers comprise silicon.

10. The method of claim 1 wherein the non-semiconductor monolayers comprise oxygen.

11. The method of claim 1 wherein the buried insulator regions comprise an oxide.

12. A method for making a semiconductor device comprising:
forming a plurality of buried spaced-apart oxide (BOX) regions in a semiconductor substrate;
forming a monocrystalline semiconductor layer on the semiconductor substrate defining respective localized semiconductor on insulator (SOI) regions above the BOX regions, and respective localized bulk semiconductor regions laterally between adjacent SOI regions;
forming a superlattice in the monocrystalline semiconductor layer, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
forming a plurality of semiconductor devices in the monocrystalline layer, with at least some of the semiconductor devices in the localized SOI regions, and at least some other semiconductor devices in the localized bulk semiconductor regions; and
forming a plurality of spaced-apart isolated oxide regions in the monocrystalline semiconductor layer.

13. The method of claim 12 wherein at least some of the isolated oxide regions extend downwardly to an adjacent buried insulator region.

14. The method of claim 12 further comprising positioning at least one memory circuit die above the monocrystalline semiconductor layer and coupled with the plurality of semiconductor devices.

15. The method of claim 12 wherein the base semiconductor monolayers comprise silicon, and the non-semiconductor monolayers comprise oxygen.

16. A method for making a semiconductor device comprising:
forming a plurality of buried spaced-apart oxide (BOX) regions in a semiconductor substrate;
forming a monocrystalline semiconductor layer on the semiconductor substrate defining respective localized semiconductor on insulator (SOI) regions above the box regions, and respective localized bulk semiconductor regions laterally between adjacent SOI regions;
forming a superlattice in the monocrystalline semiconductor layer, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
forming a plurality of semiconductor devices in the monocrystalline layer, with at least some of the semiconductor devices in the localized SOI regions, and at least some other semiconductor devices in the localized bulk semiconductor regions; and
forming a plurality of optical waveguides in the monocrystalline semiconductor layer.

17. The method of claim 16 wherein forming the plurality of semiconductor devices comprises forming at least one of an optical detector and an optical source.

18. The method of claim 16 wherein the optical waveguides comprise an oxide.

19. The method of claim 16 wherein forming the plurality of waveguides comprises forming a plurality of levels of waveguides.

20. The method of claim 16 wherein the base semiconductor monolayers comprise silicon, and the non-semiconductor monolayers comprise oxygen.
